(19) United States
(12) Patent Application Publication
(10) Pub. No.: US 2018/0198407 A1
(43) Pub. Date: Jul. 12, 2018

(54) DIRECT TEMPERATURE MEASUREMENT OVEN CONTROLLED CRYSTAL OSCILLATOR

(71) Applicant: GUANGDONG DAPU TELECOM TECHNOLOGY CO., LTD., Guangdong (CN)

(72) Inventors: Yifeng WANG, Guangdong (CN); Chaosheng LIU, Guangdong (CN)

(73) Assignee: GUANGDONG DAPU TELECOM TECHNOLOGY CO., LTD., Guangdong (CN)

(21) Appl. No.: 15/740,738

(22) PCT Filed: Jul. 27, 2015
(86) PCT No.: PCT/CN2015/085207

§ 371 Date: Dec. 28, 2017

(51) Int. Cl. H03B 5/04; H03B 5/36; H03L 1/04; H05K 1/02

(52) U.S. Cl. CPC H03B 5/04; H03B 5/36; H05K 1/167; H05K 1/0212; H03L 1/04

(57) ABSTRACT

The disclosure relates to the technical field of quartz crystal oscillators, in particular to a direct temperature measurement oven controlled crystal oscillator. The direct temperature measurement oven controlled crystal oscillator according to the present disclosure does not require additional components for measuring the temperature of the wafer inside the crystal oscillator. Instead, the temperature measurement device is disposed on the surface of the wafer to directly measure the temperature of the wafer itself, In order to achieve the exact temperature of the wafer itself. The oven controlled crystal oscillator according to the present disclosure has a simple in structure and is easy to be manufactured. The temperature of the wafer itself is directly measured to make temperature measurement more accurate.

### TECHNICAL FIELD

The present disclosure relates to a technical field of quartz crystal oscillators, and in particular, to a direct temperature measurement oven controlled crystal oscillator.

### BACKGROUND

Quartz crystal oscillators, which are oscillators with high precision and high stability, are widely applied to various oscillating circuits such as color TVs, computers and remote control, etc., and are used for frequency generators in communication systems, and are applied to generate clock signals for data processing devices and provide reference signals for specific systems. A quartz crystal oscillator is a resonating device manufactured utilizing the piezoelectric effect of quartz crystal (that is, a crystalline of silicon dioxide), and has a basic construction substantially as follows: a sheet is cut off from a piece of quartz crystal in a certain azimuth angle (wafer for short, which may be a square, a rectangle or a circle, etc.), a silver layer is coated on its two opposite sides to form electrodes, a lead is soldered to each electrode respectively to connect to a base pin, and an encapsulation shell is added, so that a quartz crystal resonator is constructed, and it is referred to as a quartz crystal, crystal or crystal resonator for short. The products thereof are generally encapsulated with metal shells, or encapsulated with glass shells, ceramic glass shells or plastic shells.

Oven controlled crystal oscillator referred to as OCXO for short is a crystal oscillator that keeps the temperature of the quartz crystal resonator in the crystal oscillator constant by means of a thermostatic bath and minimizes the variation of the output frequency of the oscillator caused by the change of ambient temperature.

The core idea of an oven controlled crystal oscillator lies in the temperature control. One of the important aspects of temperature control of the oven controlled crystal oscillator is to measure the temperature of the wafer inside the oven controlled crystal oscillator. At present, in the industry, the temperature of the wafer inside the oven controlled crystal oscillator is often measured in a way of indirect temperature measurement. As shown in FIG. 1 and FIG. 2, FIG. 1 and FIG. 2 show temperature measurement on a wafer inside an oven controlled crystal oscillator in the prior art. It may be seen from FIG. 1 and FIG. 2 that, in the conventional mode for the temperature measurement on a wafer inside an existing oven controlled crystal oscillator, a temperature measurement-related component needs to be assembled inside the oven controlled crystal oscillator. For example, in FIG. 1, it is provided with a T0-8 base 10, a ceramic substrate 11, T0-8 upper plate 12, an insulating ring 13, a metal housing 14 and a quartz wafer 15. In FIG. 2, it is provided with a T0-8 base 20, a support column 21, a ceramic substrate 23, a heat-generating device 24 and an upper cover 25.

In the conventional mode for the temperature measurement on the wafer inside the existing oven controlled crystal oscillator, a temperature measurement-related component needs to be assembled inside the oven controlled crystal oscillator, and in the prior art, measuring temperature is performed on the ceramic substrate so that such the temperature measurement is an indirect temperature measurement, that is, a temperature measurement device actually measures the temperature of the ceramic substrate thermally conductive with the wafer, rather than the temperature of the wafer itself, so that the measured temperature does not indicate an accurate temperature of the wafer itself.

### SUMMARY

In view of this, the present disclosure provides an oven controlled crystal oscillator in which it is not complex in assembling and the temperature of the wafer itself can be accurately measured.

The solutions of the disclosure are provided below.

A direct temperature measurement oven controlled crystal oscillator, which includes an upper cover, a base and a wafer, the upper cover is connected with the base to form a mounting space for the wafer, at least two support columns penetrating through the base are provided on the base, one ends of the support columns located inside the mounting space are connected to and support the wafer, and the other ends of the support columns located outside the mounting space are connected to crystal pins, and a surface of the wafer is provided with a temperature measurement device, where the temperature measurement device is connected to the one ends of the support columns located inside the mounting space.

Preferably, the wafer has a lower surface close to the base and an upper surface away from the base, and the temperature measurement device is located on the upper surface.

Preferably, the wafer has a lower surface close to the base and an upper surface away from the base, and the temperature measurement device is located on the lower surface.

Preferably, the temperature measurement device is a platinum wire, and one end of the platinum wire is connected to the one end of one of the support columns located inside the mounting space, and the other end of the platinum wire is connected to the one end of the other of the support columns located inside the mounting space.

Preferably, the temperature measurement device is a thermistor, and one end of the thermistor is connected to the one end of one of the support columns located inside the mounting space, and the other end of the thermistor is connected to the one end of the other of the support columns located inside the mounting space.

Preferably, the temperature measurement device is a digital temperature sensor, and the pins of the digital temperature sensor are connected with the one ends of the support columns located inside the mounting space, respectively.

Preferably, the surface of the wafer is further provided with a conducting wire, two ends of the conducting wire are connected with the one ends of the support columns located inside the mounting space, respectively, and the support columns connected with the conducting wire are different from the support columns connected with the temperature measurement device.

Preferably, the number of the conducting wires is two, and each of the two conducting wires has a first wire end and a second wire end far away from the first wire end, the first wire ends of the two conducting wires are connected to the one end of one of the support columns located inside the mounting space, and the second wire ends of the two conducting wires are connected to the one end of the other of the support columns located inside the mounting space.

The disclosure has the beneficial effects below:

The direct temperature measurement oven controlled crystal oscillator according to the disclosure includes: an upper cover, a base and a wafer, the upper cover is connected with the base to form a mounting space for the wafer, at least two support columns penetrating through the base are provided on the base, one ends of the support columns located inside the mounting space are connected to and support the wafer, and the other ends of the support columns located outside the mounting space are connected to crystal pins, a surface of the wafer is provided with a temperature measurement device, where the temperature measurement device is connected to the one ends of the support columns located inside the mounting space. The direct temperature measurement oven controlled crystal oscillator according to the present disclosure does not require additional components for measuring the temperature of the wafer inside the crystal oscillator. Instead, the temperature measurement device is disposed on the surface of the wafer to directly measure the temperature of the wafer itself, thereby achieving the accurate temperature measurement on the wafer itself. The direct temperature measurement oven controlled crystal oscillator according to the present disclosure has a simple in structure and is easy to be manufactured. The temperature of the wafer itself can be directly measured to make temperature measurement more accurate.

### BRIEF DESCRIPTION OF THE DRAWINGS

FIG. 1 is schematic diagram of temperature measurement on a wafer inside an oven controlled crystal oscillator in a prior art.

FIG. 2 is schematic diagram of temperature measurement on a wafer inside another oven controlled crystal oscillator in a prior art.

FIG. 3 is a schematic structural diagram of a direct temperature measurement oven controlled crystal oscillator according to the present disclosure.

FIG. 4 is a schematic structural diagram of the arrangement where a temperature measurement device is a platinum wire according to the present disclosure.

FIG. 5 is a circuit diagram of the thermistor resistance measurement according to the present disclosure.

FIG. 6 is another circuit diagram of the thermistor resistance measurement according to the present disclosure.

FIG. 7 is another schematic structural diagram of a direct temperature measurement oven controlled crystal oscillator according to the present disclosure.

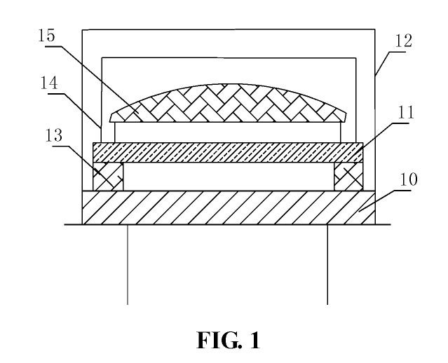

In FIG. 1:
10: T0-8 Base
11: Ceramic Substrate (on which Temperature Measurement Device is provided)
12: T0-8 Upper Cover
13: Insulating Ring
14: Metal Housing
15: Quartz Wafer

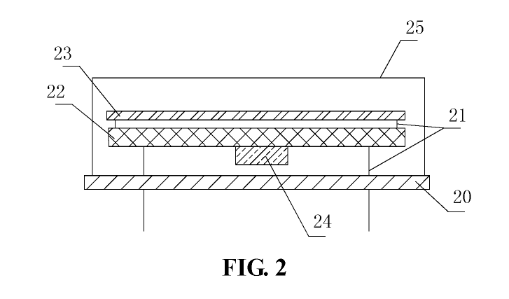

In FIG. 2:
20: Base
21: Support Column
22: Ceramic Substrate (on which Temperature Measurement Device is provided)
23: Quartz Wafer
24: Heat-Generating Device
25: Upper Cover

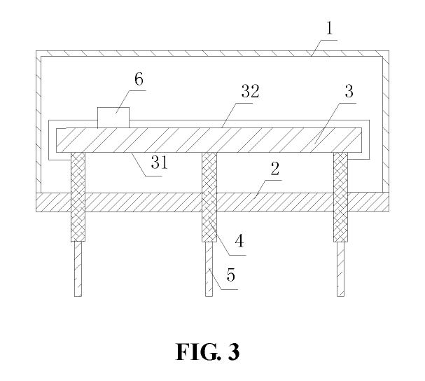

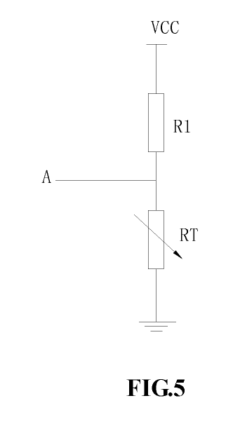

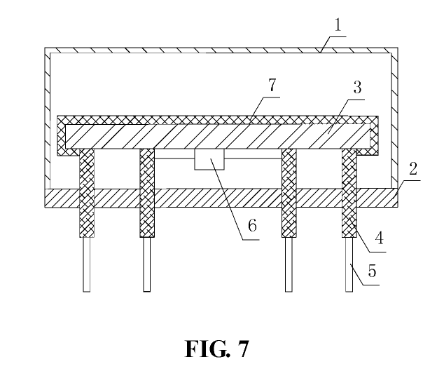

In FIG. 3, FIG. 5 and FIG. 7
1: Upper Cover
2: Base
3: Quartz Wafer
4: Support Column
5: Crystal pin
6: Temperature Measurement Device
7: Wire

### DETAILED DESCRIPTION

For one skilled in the art to better understand the solutions of the disclosure, the solutions in the embodiments of the disclosure will be described clearly and fully below in conjunction with the drawings. Apparently, the embodiments described are only a part of the embodiments of the disclosure, rather than being the whole embodiments. All other embodiments obtained by one skilled in the art based on the embodiments in the disclosure without creative effort will pertain to the protection scope of disclosure.

### Embodiment 1

Referring to FIG. 3, FIG. 3 is a schematic structural diagram of a direct temperature measurement oven controlled crystal oscillator according to the disclosure. A direct temperature measurement oven controlled crystal oscillator includes an upper cover 1, a base 2 and a wafer 3, the upper cover 1 is connected with the base 2 to form a mounting space for the wafer 3, the base 2 is provided with at least two support columns 4 penetrating through the base 2, one ends of the support columns 4 located inside the mounting space are connected to and support the wafer 3, and the other ends of the support columns 4 located outside the mounting space are connected to crystal pins 5, a surface of the wafer 3 is provided with a temperature measurement device 6, and the temperature measurement device 6 is connected to the one ends of the support columns 4 located inside the mounting space.

The temperature measurement device 6 is electrically connected to one ends of the support columns 4 inside the mounting space, and the other ends of the support columns 4 outside the mounting space are connected to the crystal pins 5, so that the temperature measurement device 6 can access an external circuit through the crystal pin 5. In conjunction with the external circuit, the temperature measurement device 6 can achieve the temperature measurement on the wafer 3.

The temperature measurement device 6 may have many specific forms. For example, the temperature measurement device 6 may be a thermistor, a temperature sensor, or the like. The number of the support columns 4 is determined by the specific form of the temperature measurement device 6. However, regardless of the specific form of the temperature measurement device 6, the temperature measurement device 6 is electrically connected to the ends of the support columns 4 located inside the mounting space in order to connect the temperature measurement device 6 to the external circuit. In the present disclosure, On the basis that the temperature measurement device 6 is connected with the ends of the support column 4 inside the mounting space to connect the temperature measurement device 6 to the external circuit, the specific number of support columns 4 may be determined according to the specific form of the temperature measurement device 6.

In this embodiment of the present disclosure, the wafer 3 has a lower surface 31 of the wafer close to the base 2 and an upper surface 32 of the wafer away from the base 2. The temperature measurement device 6 may be located on the upper surface 32 or the lower surface 31 of the wafer, which is not limited in the present disclosure.

In this embodiment, the temperature measurement device is directly disposed on the wafer to achieve accurate temperature measurement on the wafer itself. Also, no other additional temperature measurement auxiliary components are required to be mounted inside the oven controlled crystal oscillator, so that the oven controlled crystal oscillator is simple in assembling and is easy to be manufactured.

### Embodiment 2

In this embodiment, the temperature measurement device is a platinum wire.

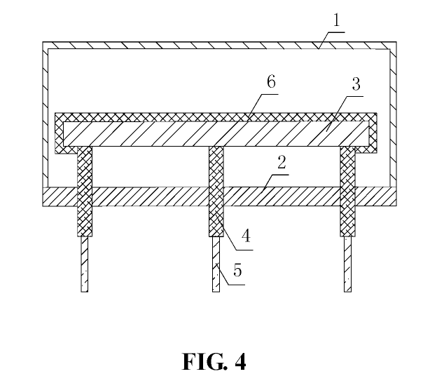

Referring to FIG. 4, FIG. 4 is a schematic structural diagram of the arrangement where the temperature measurement device is a platinum wire according to the present disclosure.

A direct temperature measurement oven controlled crystal oscillator includes an upper cover 1, a base 2 and a wafer 3, the upper cover 1 is connected to the base 2 to form a mounting space of the wafer 3, the base 2 is provided with at least two support columns 4 penetrating through the base 2. One ends of the support columns 4 located inside the mounting space are connected to and supports the wafer 3, and the other ends of the support columns 4 located outside the mounting space are connected to the crystal pins 5. A surface of the wafer 3 is provided with a temperature measurement device 6, where the temperature measurement device 6 is a platinum wire 6, one end of the platinum wire 6 is connected to the one end of one of the support columns 4 located inside the mounting space, and the other end of the platinum wire 6 is connected to the one end of the other of the support columns 4 located inside the mounting space.

The platinum wire 6 may be plated on the surface of the wafer 3 by a plating process, where the platinum wire 6 may be plated on the upper surface 32 or the lower surface 31 of the wafer, which is not limited in the present disclosure.

In the case that the platinum wire accesses external circuit through the crystal pin, the platinum wire will generate heat, thereby heating the wafer by the platinum wire; Also, based on the platinum characteristics in which there is a certain correspondence between the resistance and the temperature of Platinum, the temperature of the platinum wire can be obtained as long as the resistance of the platinum wire is known. The platinum wire is in direct contact with the wafer and the temperature of the platinum wire is just the temperature of the wafer, so that the platinum wire can achieve the temperature measurement on the wafer; Based on this, the platinum wire are plated on the surface of the wafer, thereby both heating the wafer and measuring the temperature of the wafer.

The platinum wire accesses the external circuit through the crystal pin, so that the resistance of the platinum wire can be obtained. There are many ways to obtain the resistance of the platinum wire. For example, the method for obtaining the resistance of the thermistor in the embodiment 3 of the present disclosure is also applicable to the platinum wire in this embodiment, and the specific process is not described herein again.

After obtaining the resistance of the platinum wire, the temperature of the platinum wire can be obtained by referring to the table of the “resistance−temperature” correspondence of the platinum wire. The platinum wire is in direct contact with the wafer, and the temperature of the platinum wire is just the temperature of the wafer.

It should be noted that, because the resistance of the platinum wire is closely related to a length and a cross-sectional area thereof, different lengths and different cross-sectional areas of the platinum wire determine the different “resistance−temperature” correspondences.

In this embodiment, the platinum wire is directly disposed on the wafer to directly heat the wafer and accurately measure the temperature of the wafer itself. Also, it is not necessary to mount other additional heating and temperature measurement auxiliary components inside the oven controlled crystal oscillator, so that the oven controlled crystal oscillator is simple in assembling and is easy to to be manufactured.

### Embodiment 3

In this embodiment, the temperature measurement device is a thermistor.

Referring to FIG. 3, a direct temperature measurement oven controlled crystal oscillator includes: an upper cover 1, a base 2 and a wafer 3. The upper cover 1 is connected with the base 2 to form a mounting space for the wafer 3, and at least two support columns 4 penetrating through the base 2 are provided on the base 2. One ends of the support columns 4 located inside the mounting space are connected to and support the wafer 3. The other ends of the support columns 4 located at the mounting space are connected with the crystal pins 5. A surface of the wafer 3 is provided with a temperature measurement device 6. The temperature measurement device 6 is a thermistor 6, and one end of the thermistor 6 is connected to the one end of one of the support columns 4 located inside the mounting space, and the other end of the thermistor 6 is connected to the one end of the other of the support columns 4 located inside the mounting space.

The thermistor 6 may be located on the upper surface 32 or the lower surface 31 of the wafer, which is not limited in the present disclosure.

The thermistor is a type of sensitive components. According to the temperature coefficient, the thermistor can be classified as a positive temperature coefficient thermistor (PTC) and a negative temperature coefficient thermistor (NTC). A typical characteristic of the thermistor is temperature-sensitive. Different temperatures exhibits different resistance values, that is, the thermistor has a “resistance−temperature” correspondence. Two methods for measuring the resistance of the thermistor are proposed below to obtain the temperature of the wafer currently measured by the thermistor.

1: as shown in FIG. 5, a crystal pin connected to one end of the thermistor RT is grounded, a crystal pin connected to the other end of the thermistor RT is connected to one end of a resistor R1, and the other end of the resistor R1 is connected to a voltage VCC. The voltage VCC is known and the resistor R1 is known. In FIG. 5, the voltage at the voltage measurement point A can be measured. Assuming that the voltage at the voltage measurement point A is V, then VCC/(R1+RT)=V/RT. In this formula of VCC/(R1+RT)=V/RT, since VCC is known, R1 is known and V is known, the resistance of the thermistor RT can be obtained.

Since the thermistor RT has a “resistance−temperature” correspondence, the current temperature of the thermistor RT can be obtained based on the obtained resistance of the thermistor RT. The thermistor RT is disposed on the wafer, the current temperature of the thermistor RT is just the current temperature of the wafer.

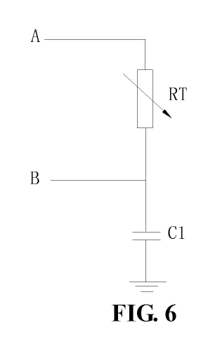

2: as shown in FIG. 6, a capacitor C1 and a thermistor RT are connected as shown in FIG. 6. The size of the capacitor C1 is known. A voltage is applied at the terminal A to charge the capacitor C1. During the charging of the capacitor C1, the voltage at the terminal B will get higher and higher over time, until the capacitor C1 is fully charged. The resistance of the thermistor RT can be calculated through charge and discharge principle of the resistor and the capacitor. For example, a voltage is applied at the terminal A to charge the capacitor C1, and at the time t, the voltage at terminal B reaches Vt. Then, the resistance of the thermistor RT can be calculated by the formula t=RT*C*Ln [(V1−V0)/(V1−Vt)], where C is the capacitance of the capacitor C1, V1 is the voltage applied to the A terminal during charging, V0 is an initial voltage of the capacitor C1 at beginning of charging, and Vt is the voltage of the capacitor C1 at time t.

3: in the above formula, t, C, V1, V0, Vt are all known, and hence R can be obtained, that is, the resistance of the thermistor RT in FIG. 6 can be obtained.

Since the thermistor RT has a “resistance−temperature” correspondence, the current temperature of the thermistor RT can be obtained based on the obtained resistance of the thermistor RT; thermistor RT is disposed on the wafer, the current temperature of the thermistor RT is just the current temperature of the wafer.

In the disclosure, the thermistor is directly arranged on the wafer to realize accurate temperature measurement on the wafer itself; Also, no other additional temperature measurement auxiliary components are required to be mounted inside the oven controlled crystal oscillator so that the oven controlled crystal oscillator is simple in assembling and is easy to be manufactured.

### Embodiment 4

In this embodiment, the temperature measurement device is a digital temperature sensor.

Referring to FIG. 3, a direct temperature measurement oven controlled crystal oscillator includes: an upper cover 1, a base 2 and a wafer 3. The upper cover 1 is connected with the base 2 to form a mounting space for the wafer 3. At least two support columns 4 penetrating through the base 2 are disposed on the base 2. One ends of the support columns 4 located inside the mounting space are connected to and supports the wafer 3, and the other ends of the support columns 4 located outside the mounting space are connected to the crystal pins 5. A surface of the wafer 3 is provided with a temperature measurement device 6. The temperature measurement device 6 is a digital temperature sensor 6, the pins of the digital temperature sensor 6 are connected to the one ends of the support columns 4 located inside the mounting space, respectively.

The digital temperature sensor 6 may be located on an upper surface 32 or a lower surface 31 of the wafer, which is not limited in the present disclosure.

This embodiment takes a DS1820 digital temperature sensor as an example for description. The DS1820 digital temperature sensor has three pins: a ground pin, a power pin, and a signal pin. A DS1820 digital temperature sensor 6 is arranged on a surface of the wafer 3. Three pins of the DS1820 digital temperature sensor 6 are respectively connected with the one ends of the support columns 4 located inside the mounting space. That is, the three pins of the DS1820 digital temperature sensor 6 are connected to three crystal pins 5 through different three support column 4. The three crystal pins 5 correspond to the three pins of the DS1820 digital temperature sensor 6. Through the three crystal pins 5, the DS1820 digital temperature sensor 6 can access the external circuit, and the DS1820 digital temperature sensor 6 can work to obtain the temperature of the wafer 3.

The difference between the digital temperature sensor and the traditional thermistor lies in that, the digital temperature sensor uses the integrated chip and utilizes a single bus technology, which can effectively reduce the external interference and improve measurement accuracy. Furthermore, it can directly convert the measured temperature into a serial digital signal for computer processing, and it has a simple interface, which enables data transmission and processing simple.

In the disclosure, the digital temperature sensor is directly arranged on the wafer to realize accurate temperature measurement on the wafer itself; Further, no other temperature measurement auxiliary components are required to be mounted inside the oven controlled crystal oscillator, so that the oven controlled crystal oscillator is simple in assembling and is easy to be manufactured.

### Embodiment 5

The core of the oven controlled crystal oscillator lies in temperature control, and the temperature control contains two aspects: heating the wafer and measuring the temperature of the wafer. In an embodiment of the present disclosure for both heating the wafer and measuring the temperature of the wafer: a heating wire is arranged on an upper surface of the wafer; a temperature measurement device is arranged on a lower surface of the wafer; so that both heating to the wafer and temperature measurement on the wafer are realized.

Referring to FIG. 7, a direct temperature measurement oven controlled crystal oscillator includes an upper cover 1, a base 2 and a wafer 3. The upper cover 1 is connected with the base 2 to form a mounting space for the wafer 3. At least two support columns 4 penetrating through the base 2 are provided on the base 2. One ends of the support columns 4 located inside the mounting space are connected to and support the wafer 3. The other ends of the support columns 4 located outside the mounting space are connected to crystal pins 5, the upper surface of the wafer 3 is provided with a conducting wire 7, two ends of the conducting wire 7 are connected to the one ends of the support columns 4 located inside the mounting space, respectively. The lower surface of the wafer 3 is provided with a temperature measurement device 6. The temperature measurement device 6 is electrically connected to the one ends of the support columns 4 located inside the mounting space. The support columns connected with the conducting wire 7 are different from the support columns connected with the temperature measurement device 6.

The conducting wire 7 is connected to an external circuit to heat the wafer 3; the temperature measurement device 6 is connected to an external circuit to measure the temperature of the wafer 3.

In order to achieve better heating effect, two conducting wires 7 may be connected in parallel. The parallel structure of two conducting wires is that, the number of the conducting wires are two, each of the two wires has a first wire end and a second wire end far away from the wire first end, and the first wire ends of the two conducting wires are connected together to the one end of one of the support columns located inside the mounting space, and the second wire ends of the two conducting wires are connected together to the one end of the other of the support columns located inside the mounting space.

In summary, in the present disclosure the temperature measurement device is directly disposed on the wafer to realize accurate temperature measurement on the wafer itself, and further, there is no need to mount other temperature measuring auxiliary components inside the oven controlled crystal oscillator, so that the oven controlled crystal oscillator is simple in assembling and is easy to be manufactured.

The principles of the disclosure have been described above in conjunction with specific embodiments. These descriptions are merely provided to explain the principles of the disclosure, rather than limiting the protection scope of the disclosure in any way. On the basis of the explanation herein, other embodiments may be obtained by one skilled in the art without creative effort, and all these embodiments will fall into the protection scope of the disclosure.

What is claimed is:

1. An oven controlled crystal oscillator, comprising:
an upper cover, a base and a wafer, wherein the upper cover is connected to the base to form a mounting space for the wafer, and at least two support columns penetrating through the base are provided on the base, one ends of the support columns located inside the mounting space are connected to and support the wafer, and the other ends of the support columns located outside the mounting space are connected to crystal pins, a surface of the wafer is provided with a temperature measurement device, and the temperature measurement device is connected to the one ends of the support columns located inside the mounting space.

2. The oven controlled crystal oscillator according to claim 1, wherein
the wafer has a lower surface close to the base and an upper surface away from the base, and the temperature measurement device is disposed on the upper surface of the wafer.

3. The oven controlled crystal oscillator according to claim 1, wherein
the wafer has a lower surface close to the base and an upper surface away from the base, and the temperature measurement device is disposed on the lower surface of the wafer.

4. The oven controlled crystal oscillator according to claim 2, wherein
the temperature measurement device is a platinum wire, and
one end of the platinum wire is connected to the one end of one of the support columns located inside the mounting space, and the other end of the platinum wire is connected to the one end of the other of the support columns located inside the mounting space.

5. The oven controlled crystal oscillator according to claim 2, wherein
the temperature measurement device is a thermistor, and
one end of the thermistor is connected to the one end of one of the support columns located inside the mounting space, and the other end of the thermistor is connected to the one end of the other of the support columns located inside the mounting space.

6. The oven controlled crystal oscillator according to claim 2, wherein
the temperature measurement device is a digital temperature sensor, and
the pins of the digital temperature sensor are connected with the one ends of the support columns located inside the mounting space, respectively.

7. The oven controlled crystal oscillator according to claim 1, wherein
the surface of the wafer is further provided with a conducting wire, two ends of the conducting wire are connected to the one ends of the support columns located inside the mounting space, respectively, and
the support columns connected with the conducting wire are different from the support columns connected with the temperature measurement device.

8. The oven controlled crystal oscillator according to claim 7, wherein
the number of the conducting wires is two, each of the conducting wires has a first wire end and a second wire end far away from the first wire end, and
The first wire ends of the two conducting wires are connected together to the one end of one of the support columns located inside the mounting space and the second wire ends of the two conducting wires are connected together to the one end of the other of the support columns located in the mounting space.
